(19) United States
(12) Patent Application Publication
(10) Pub. No.: US 2006/0134921 A1
(43) Pub. Date: Jun. 22, 2006

(54) Plasma etching process

(76) Inventors: Chih-Ning Wu, Hsinchu (TW); Wen-Sheng Chien, Hsinchu (TW)

Correspondence Address: J.C. Patents, Suite 250, 4 Venture, Irvine, CA, 92618, US

(21) Appl. No.: 11/295,680

(22) Filed: Dec. 5, 2005

Related U.S. Application Data
(63) Continuation-in-part of application No. 10/428,507, filed on May 1, 2003, now abandoned.

(51) Int. Cl. C23F 1/00; H01L 21/461; H01L 21/302

(52) U.S. Cl. 438/710; 438/706; 216/67

(57) ABSTRACT

A plasma etching process is described. A substrate having a low-k material layer and a metal hard mask layer sequentially formed thereon is provided, wherein the metal hard mask layer exposes a portion of the low-k material layer. The low-k material layer is then etched with plasma of a gas mixture of helium (He) and at least one fluorinated hydrocarbon by using the metal hard mask layer as a mask.

### CROSS-REFERENCE TO RELATED APPLICATION

This application is a continuation-in-part of a prior application Ser. No. 10/428,507, filed May 1, 2003. All disclosures are incorporated herewith by reference.

### BACKGROUND OF THE INVENTION

1. Field of the Invention

The present invention relates to a semiconductor process. More particularly, the present invention relates to a plasma etching process free of organo-metallic polymer contamination.

2. Description of the Related Art

In advanced semiconductor processes like 90 nm CMOS processes, 193 nm photoresist materials are required for forming small patterns. In the meantime, low-resistance metal materials like copper and low-k dielectric materials are usually adopted in multi-level interconnect structures for reducing RC delay effect. As a low-k material layer is to be patterned using a 193 nm photoresist material, a metal hard mask layer is required since the dry-etching resistance of a 193 nm photoresist material is low.

In the prior art, a low-k material layer is dry-etched with plasma generated from a gas mixture of Ar/CF₄/C₄F₈/N₂, Ar/CF₄/C₄F₈/O₂ or Ar/N₂/C₄F₈. A metal hard mask layer is more resistant to the plasma than a conventional SiN hard mask layer in such an etching process, however, organo-metallic polymer is easily formed contaminating the substrate because of back-sputtering and bombardment effects on the metal hard mask layer caused by Ar ions. For example, in an etching process for forming dual damascene openings, organo-metallic polymer is easily deposited on sidewalls of via holes and trenches. The organo-metallic polymer is difficult to remove, and will alter the resistance of via plugs and conductive lines that are formed later.

### SUMMARY OF THE INVENTION

In view of the forgoing, this invention provides a plasma etching process that is free of organo-metallic polymer contamination as a metal layer is also exposed in the plasma.

This invention also provides a plasma etching process utilizing a metal hard mask layer, which is free of organo-metallic polymer contamination.

This invention further provides a dual damascene process that is based on the plasma etching process of this invention.

In the plasma etching process of this invention, a gas mixture of helium (He) and at least one fluorinated hydrocarbon is used to generate plasma for etching a low-k material, while a metal layer is also exposed in the plasma.

In the plasma etching process utilizing a metal hard mask layer of this invention, a substrate having a low-k material layer and a metal hard mask layer sequentially formed thereon is provided, wherein the metal hard mask layer exposes a portion of the low-k material layer. The low-k material layer is then etched with plasma of a gas mixture of helium (He) and at least one fluorinated hydrocarbon by using the metal hard mask layer as a mask. The etching step may define a via hole, a trench, or a dual damascene opening in the low-k material layer.

The dual damascene process of this invention is described as follows. A substrate having a stack of a low-k material layer and a metal hard mask layer thereon is provided, wherein the low-k material layer has a hollow of via-hole pattern therein, and the metal hard mask layer is defined with a trench pattern over the hollow. The low-k material layer is then etched with plasma of a gas mixture of helium (He) and at least one fluorinated hydrocarbon to form a trench in the low-k material layer with the metal hard mask layer as a mask, and to deepen the hollow to complete a via hole in the low-k material layer.

In this invention, the bombardment and back sputtering effects on the metal (hard mask) layer is significantly reduced since helium ions are much lighter than argon ions, and formation of organo-metallic polymer therefore can be prevented. Therefore, by utilizing the dual damascene process based on the plasma etching process of this invention, organo-metallic polymer is not deposited on sidewalls of via holes and trenches, and the resistance of via plugs and conductive lines will not shift.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1-7 illustrate a method for forming a dual damascene opening according to a preferred embodiment of this invention in a cross-sectional view, the method for forming the dual damascene opening being based on the plasma etching process of this invention.

### DESCRIPTION OF THE PREFERRED EMBODIMENTS

The present invention will be further explained with a dual damascene process as a preferred embodiment. However, the present invention is not restricted to use in dual damascene processes, and can be used in any case where a low-k material is etched with a metal layer being exposed in the etching plasma simultaneously.

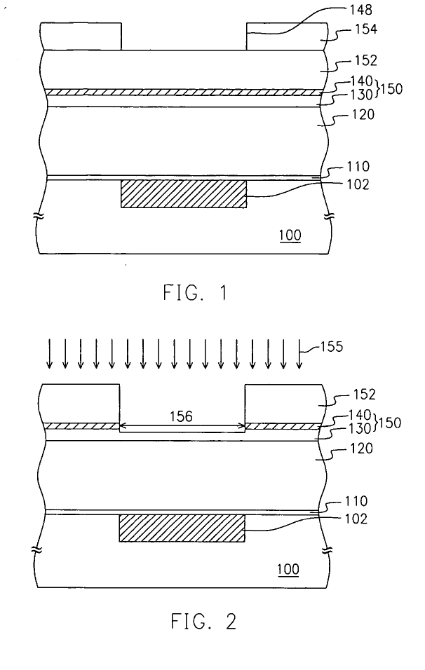

FIGS. 1-7 illustrate a method for forming a dual damascene opening according to a preferred embodiment of this invention in a cross-sectional view. The method for forming the dual damascene opening is based on the plasma etching process of this invention, and may be a 90 nm semiconductor process.

Referring to FIG. 1, a substrate 100 is provided with a conductive layer 102 to be connected formed therein, wherein the conductive layer 102 may comprise a low-resistance metallic material like copper. A protective layer 110, such as a SiN layer, is formed on the substrate 100 covering the conductive layer 102. The protective layer 110 is taken as an etching stop layer in the later performed process. A low-k material layer 120 is formed on the protective layer 110, comprising a material such as porous silicon oxide, hydrogen silsesquioxane (HSQ), methyl silsesquioxane (MSQ) or fluorinated glass (FSG). A non-metal hard mask layer 130 and a metal hard mask layer 140, which two constitute a hard mask layer 150 together, are sequentially formed on the low-k material layer 120. The non-metal hard mask layer 130 may comprise SiC, and the metal hard mask layer 140 comprises TiN or TaN, for example. Thereafter, a bottom anti-reflection coating (BARC) 152 and a photoresist layer 154 having a trench pattern 148 of a dual damascene structure are sequentially formed on the metal hard mask layer 140, wherein the photoresist layer 154 may comprise a 193 nm photoresist material.

Referring to FIGS. 1-2, anisotropic etching 155 is performed with the photoresist layer 154 (FIG. 1) as a mask to etch away the exposed BARC 152 and then transfer the trench pattern 148 to the hard mask layer 150, while the trench pattern on the hard mask layer 150 is labeled with “156”. It is noted that the photoresist layer 154 has been completely etched away, and the underlying BARC 152 is exposed serving as a new etching mask in FIG. 2.

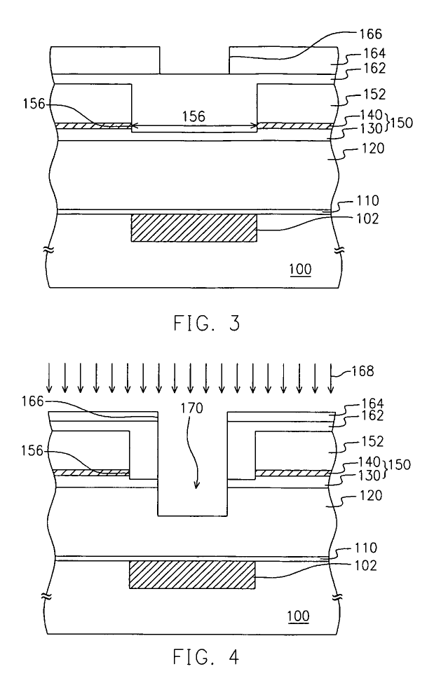

Referring to FIG. 3, a new BARC 162 and a photoresist layer 164 having a via-hole pattern 166 of the dual damascene structure are sequentially formed on the substrate 100, wherein the via-hole pattern 166 is located over the trench pattern 156 in the hard mask layer 150.

Referring to FIGS. 3-4, anisotropic etching 168 is performed with the photoresist layer 164 as a mask to sequentially etch away the BARC 162 and the non-metal hard mask layer 130 exposed in the via-hole pattern 166, and then partially etch the exposed low-k material layer 120 to form a hollow 170 of via-hole pattern in the low-k material layer 120.

Referring to FIG. 5, a photoresist stripping process is performed to completely remove the remaining photoresist layer 164. The photoresist stripping process utilizes, for example, an alkaline stripping solution such as 3% NaOH solution.

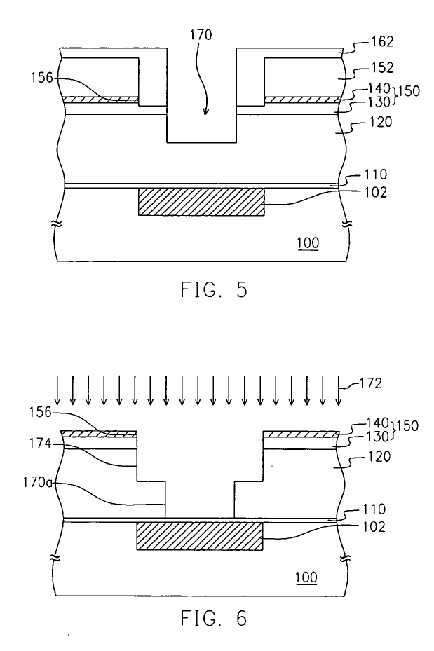

Referring to FIG. 6, anisotropic etching 172 is performed with plasma of a gas mixture of He and at least one fluorinated hydrocarbon like CF₄, and the gas mixture may further include another fluorinated hydrocarbon, such as C₄F₈ or C₄F₆, for better control of the etching process. As He/CF₄/C₄F₈ are used as etching gases, it is preferable that He is introduced with a flow rate of 75-500 sccm, CF₄ with a flow rate of 18-30 sccm, and C₄F₈ with a flow rate of 3-8 sccm. After the bottom anti-reflection coatings 162 and 152 (FIG. 5) are etched away, the metal hard mask layer 140 serves as a new etching mask. The low-k material layer 120 under the trench pattern 156 but not under the hollow 170 is etched with the metal hard mask layer 140 as a mask after the exposed non-metal hard mask layer 130 is removed, whereby a trench 174 is formed in the low-k material layer 120. Meanwhile, the depth of the hollow 170 of via-hole pattern is continuously increased because of the etching effect, so that a via hole 170a is completed in the low-k material layer 120 finally. The via hole 170a and the trench 174 together form a rude dual damascene hole.

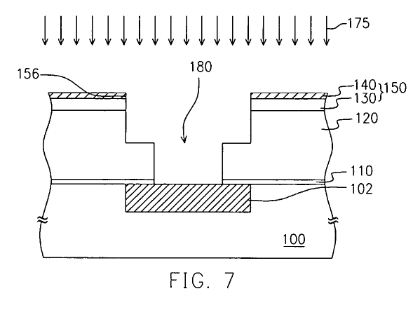

The subsequent processes for completing a dual damascene structure include removing the exposed protective layer 110, removing the metal hard mask layer 140 and filling a metallic material into the via hole 170a and the trench 174 to form a via plug and a trench, etc. As shown in FIG. 7, a step of removing the exposed protective layer 110 is accomplished by performing an etching process 175, such as a plasma etching process until the conductive layer 102 is exposed. Therefore, a dual damascene opening 180 exposing a portion of the conductive layer 102 is formed. The plasma used in the plasma etching process is generated from a gas mixture of He and at least one halogen-containing gas. The halogen-containing gas can be, for example but not limited to, a carbon fluoride and the halogen-containing gas is selected from a group consisting of CF₄, C₄F₈, C₄F₆, and the combination thereof. It is preferable that the operation pressure of the plasma etching process is about 10-200 mTorr and the plasma etching process is performed under that the top power of the chamber is about 450 W and the bottom power of the chamber is about 300 W. Moreover, helium is introduced with a flow rate of about 75-500 sccm and CF₄ is introduced with a flow rate of 75-500 sccm. For example, as He/CF₄/C₄F₈ are used as etching gases, it is preferable that He is introduced with a flow rate of 75-500 sccm, CF₄ with a flow rate of 18-30 sccm, and C₄F₈ with a flow rate of 3-8 sccm. Preferably, the plasma etching process for removing the exposed portion of the protective layer 110 is lasting for about 30 sec with the operation pressure of 100 mTorr, the flow rate of helium of about 140 sccm and the flow rate of CF₄ of about 140 sccm as well. That is, the ratio of the helium to halogen-containing gas in the gas mixture is about 1.

In this invention, the bombardment and back sputtering effects on the metal (hard mask) layer is significantly reduced since helium ions are much lighter than argon ions, and formation of organo-metallic polymer therefore can be prevented. Therefore, by utilizing the dual damascene process based on the plasma etching process of this invention, organo-metallic polymer is not deposited on sidewalls of via holes and trenches, and the resistance of via plugs and conductive lines will not shift. In addition, since the helium is used as a major gas for generating the plasma in the step of removing the exposed portion of the protective layer, the surface of the conductive layer can be prevented from being damaged by the particles of the plasma during the plasma etching process. Furthermore, because the plasma is generated from a helium-dominated gas mixture, the etching profile of the exposed protective layer can be well controlled even through the thickness of the protective layer is relatively small. Hence, the conductive layer is prevented from being over etched.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A plasma etching process for removing a portion of a protective layer over a substrate to expose a conductive layer on the substrate, wherein at least one dielectric layer is located over the protective layer and at least one opening penetrates through the dielectric layer and exposes the portion of the protective layer, the plasma etching process comprising:
etching the portion of the protective layer until the conductive layer is exposed, wherein a plasma used to etch the portion of the protective layer is generated from a gas mixture of helium (He) and at least one halogen-containing gas.

2. The plasma etching process of claim 1, wherein the halogen-containing gas comprises is selected from a group consisting of CF₄, C₄F₈, C₄F₆, and the combination thereof.

3. The plasma etching process of claim 1, wherein, during the step of etching the portion of the protective layer, a metal layer is a topmost layer on the dielectric layer and is directly exposed to the plasma.

4. The plasma etching process of claim 1, wherein a ratio of He to the halogen-containing gas is about 1.

5. The plasma etching process of claim 1, wherein during the step of etching the portion of the protective layer, the flow rate of He is about 140 sccm and the flow rate of halogen-containing gas is about 140 sccm.

6. A method for forming an opening for a substrate having a conductive layer, an etching stop layer, at least one dielectric layer and a metal layer formed thereon sequentially, wherein a hole penetrates through the metal layer and the dielectric layer and exposes a portion of the etching stop layer, the method comprising:
performing an etching process to remove the exposed portion of the etching stop layer until a portion of the conductive layer is exposed so that an opening is formed, wherein a gas mixture of helium (He) and at least one carbon fluoride is used in the etching process and the metal layer directly confronts a plasma generated from the gas mixture.

7. The method of claim 6, wherein the carbon fluoride is selected from a group consisting of CF₄, C₄F₈, C₄F₆ and the combination thereof.

8. The method of claim 6, wherein, in the step of performing the etching process, He is introduced with a flow rate of 75-500 sccm.

9. The method of claim 6, wherein the dielectric layer comprises a material selected from a group consisting essentially of porous silicon oxide, hydrogen silsesquioxane (HSQ), methyl silsesquioxane (MSQ) and fluorinated glass (FSG).

10. The method of claim 6, wherein the metal layer comprises TiN or TaN.

11. The method of claim 6, wherein the opening can be a via hole, a trench, or a dual damascene opening in the dielectric layer.

12. A method for forming a dual damascene opening, comprising:
providing a substrate having a stack of a conductive layer, a protective layer, a low-k material layer and a metal hard mask layer thereon, wherein a rude dual damascene hole penetrates through the metal hard mask layer and the low-k material layer and exposes a portion of the protective layer; and
etching the exposed protective layer with a plasma generated from a gas mixture of helium (He) and at least one carbon fluoride to transform the rude dual damascene hole into a dual damascene opening exposing a portion of the conductive layer.

13. The method of claim 12, wherein the carbon fluoride is selected from a group consisting of CF₄, C₄F₈, C₄F₆ and the combination thereof.

14. The method of claim 12, wherein He is introduced with a flow rate of 75-500 sccm.

15. The method of claim 12, wherein the low-k material layer comprises a material selected from a group consisting essentially of porous silicon oxide, hydrogen silsesquioxane (HSQ), methyl silsesquioxane (MSQ) and fluorinated glass (FSG).

16. The method of claim 12, wherein the metal hard mask layer comprises TiN or TaN.

17. The method of claim 12, wherein providing the substrate having a stack of the low-k material layer and the metal hard mask layer thereon comprises:
sequentially forming a blanket low-k material layer and a blanket metal layer on a substrate;
defining the trench pattern in the blanket metal layer; and
forming the rude dual damascene hole in the low-k material layer and the metal hard mask layer.

18. The method of claim 12, wherein during the step of etching the exposed portion of the protective layer, the flow rate of He is about 140 sccm and the flow rate of halogen-containing gas is about 140 sccm.

19. The method of claim 12, wherein a ratio of He to the halogen-containing gas is about 1.
